(19) United States
(12) Patent Application Publication
(10) Pub. No.: US 2026/0150466 A1
(43) Pub. Date: May 28, 2026

(54) DISPLAY DEVICE

(71) Applicant: LG Display Co., Ltd., Seoul (KR)

(72) Inventors: Soyoung Lee, Seoul (KR); Hun Jang, Paju-si (KR); Soyi Lee, Paju-si (KR); YoungIn Jang, Paju-si (KR)

(73) Assignee: LG Display Co., Ltd., Seoul (KR)

(21) Appl. No.: 19/344,014

(22) Filed: Sep. 29, 2025

(30) Foreign Application Priority Data
Nov. 27, 2024 (KR) 10-2024-0172622

(51) Int. Cl. H10H 29/80; H10H 29/01; H10H 29/49; H10H 29/853

(52) U.S. Cl. CPC H10H 29/8325; H10H 29/012; H10H 29/032; H10H 29/034; H10H 29/0362; H10H 29/49; H10H 29/8323; H10H 29/842; H10H 29/853

(57) ABSTRACT

A display device including a substrate; a driving transistor on the substrate; an adhesive layer on the substrate; a light emitting diode on the adhesive layer and overlapping with the driving transistor and having a first semiconductor layer on the adhesive layer, an emission layer on the first semicondutor layer, a second semiconductor layer on the emission layer, a first electrode on the first semiconductor layer, and a second electrode on the second semiconductor layer, wherien the first electrode is disposed closer to the substate than the emission layer, and the second electrode is disposed higher than the first electrode; a reflective connection electrode covering a lower side surface of the light emitting diode and the first electrode and electrically connecting the first electrode to the driving transistor; and a transparent connection electrode overlapping the reflective connection electrode, contacting a top surface of the light emitting diode and elecrically connecting the second electrode to a power line on the substrate.

### CROSS-REFERENCE TO RELATED APPLICATIONS

This application claims the priority of Korean Patent Application No. 10-2024-0172622, filed on November 27, 2024, in the Korean Intellectual Property Office, the entirety of the disclosure of which is incorporated into the present application herein by reference.

### BACKGROUND

### FIELD

The present disclosure relates to a display device, and more particularly to a display device which improves a front luminance.

### DISCUSSION OF THE RELATED ART

Display devices as used in various applications, such as computer monitors, televisions, and cellular phones. Among these display devices, some displays use an organic light emitting display device (OLED), which is a self-emitting device, while other displays use a liquid crystal display device (LCD), which uses a separate light source. An applicable range of the display device is diversified to personal digital assistants as well as monitors of computers and televisions and a display device with a large display area and a reduced volume and weight is being studied.

Further, display devices including a light emitting diode (LED) are attracting attention as a next generation display technology. Because LEDs include inorganic materials rather than organic materials, reliability is excellent so a lifespan thereof is longer than a lifespan of the liquid crystal display device or the organic light emitting display device. Further, inorganic LEDs have a fast lighting speed, excellent luminous efficiency, and a strong impact resistance so a stability is excellent and an image having a high luminance can be displayed.

### SUMMARY

Accordingly, one object of the present disclosure is to provide a display device with an improved front luminance. Another object of the present disclosure is to provide a display device with improved light extraction efficiency from the light emitting diodes. Still another object of the present disclosure is to provide a display device in which a process cost and time are saved by reducing the number of masks used for the manufacturing process. Objects of the present disclosure are not limited to the above-mentioned objects, and other objects, which are not mentioned above, can be clearly understood by those skilled in the art from the following descriptions.

According to an aspect of the present disclosure, a display device includes a substrate in which a plurality of sub pixels are defined; a plurality of driving transistors in each of the plurality of sub pixels; a plurality of light emitting diodes in each of the plurality of sub pixels; a first connection electrode covering a part of a lower side surface of the plurality of light emitting diodes and formed of a reflective conductive material; and a second connection electrode in contact with top surfaces of the plurality of light emitting diodes and formed of a transparent conductive material.

According to another aspect of the present disclosure, a display device includes a substrate in which a plurality of sub pixels are defined; a plurality of driving transistors in each of the plurality of sub pixels; a first planarization layer on the plurality of driving transistors; a plurality of light emitting diodes on the first planarization layer in each of the plurality of sub pixels; a first connection electrode electrically connected to the plurality of light emitting diodes and formed of a reflective conductive material; a second connection electrode electrically connected to the plurality of light emitting diodes and formed of a transparent conductive material; and a second planarization layer between the first connection electrode and the second connection electrode with the second planarization layer including a black material. Other detailed matters of the embodiments are included in the detailed description and the drawings.

According to the embodiment of the present disclosure, the number of manufacturing processes of a planarization layer is reduced to lessen the number of masks used for the manufacturing processes, thereby saving process cost and time while implementing process optimization. Also, the number of manufacturing processes is reduced by using the planarization layer as a mask to implement process optimization. Further, laterally traveling light is reflected to the front direction to improve the front luminance, which allows the light emitting diode to be driven at a low power.

Therefore, an amount of light trapped in the light emitting diode is reduced to improve the light extraction efficiency, which allows the light emitting diode to be driven at a low power. The effects according to the present disclosure are not limited to the contents exemplified above, and more various effects are included in the present specification.

### BRIEF DESCRIPTION OF DRAWINGS

The above and other objects, features, and other advantages of the present disclosure will be more clearly understood to those of ordinary skill in the art from the following detailed description taken in conjunction with the accompanying drawings, in which:

FIG. 1 is a schematic diagram of a display device according to an embodiment of the present disclosure;

FIG. 2 is an enlarged cross-sectional view of a display device according to an embodiment of the present disclosure;

FIGS. 3A to 3E are views for explaining a manufacturing method of a display device according to an embodiment of the present disclosure;

FIG. 4 is a graph illustrating a luminance according to a viewing angle of a display device according to an embodiment of the present disclosure;

FIG. 5 is an enlarged cross-sectional view of a display device according to another embodiment of the present disclosure;

FIGS. 6A to 6D are views for explaining a manufacturing method of a display device according to another embodiment of the present disclosure; and

FIG. 7 is an enlarged cross-sectional view of a display device according to still another embodiment of the present disclosure.

### DETAILED DESCRIPTION OF THE EMBODIMENT

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so those skilled in the art can fully understand the disclosures of the present disclosure and the scope of the present disclosure. The features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated. When the position relation between two parts is described using the terms such as “on,” “above,” “below,” and “next,” one or more parts can be positioned between the two parts unless the terms are used with the term “immediately” or “directly”. When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated. The features of various embodiments of the present disclosure can be partially or entirely adhered to or combined with each other and can be interlocked and operated in technically various ways, and the embodiments can be carried out independently of or in association with each other.

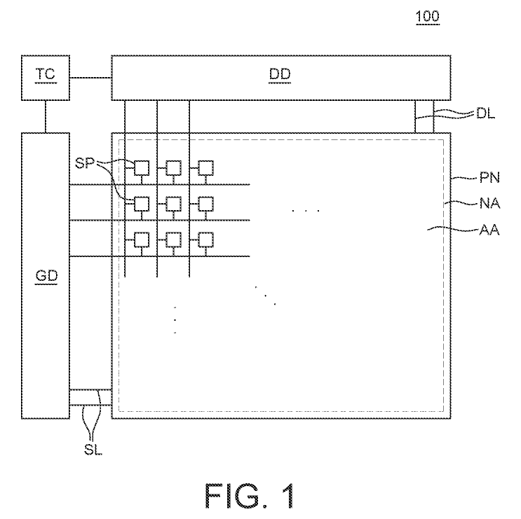

Hereinafter, the present disclosure will be described in detail with reference to accompanying drawings. In particular, FIG. 1 is a schematic diagram of a display device according to an embodiment of the present disclosure. FIG. 1 illustrates the display device 100,incliding a display panel PN, a gate driver GD, a data driver DD, a plurality of sub pixels SP, and a timing controller TC are illustrated.

Referring to FIG. 1, the display device 100 includes the display panel PN, which includes the plurality of sub pixels SP, the gate driver GD, and the data driver DD which supply various signals to the display panel PN. In addition, the timing controller TC controls the gate driver GD and the data driver DD.

A driver, such as a gate driver GD, a data driver DD, and a timing controller TC, can be connected to the display panel PN in various ways. For example, the gate driver GD can be mounted in a non-active area NA in a gate in panel (GIP) manner or mounted between the plurality of sub pixels SP in an active area AA in a gate in active area (GIA) manner.

Also, the display panel PN displays images to the user and includes sub pixels SP, scan lines SL, and data lines DL intersecting each other. As shown, each sub pixel SP is connected to the scan lines SL and the data lines DL, respectively. In addition, each sub pixel SP can be connected to a high potential power line, a low potential power line, and a reference line.

As shown in FIG. 1, the display panel PN includes an active area AA and a non-active area NA surrounding the active area AA. The active area AA displays images in the display device 100 and includes sub pixels SP can be configured to constitute a plurality of pixels, and a circuit for driving the sub pixels SP. Also, the sub pixel SP is a minimum unit which configures the active area AA and n sub pixels SP can form one pixel. In each sub pixel SP, a light emitting diode and a thin film transistor for driving the light emitting diode are disposed. In additon, the light emitting diodes can be defined in different manners depending on the type of the display panel PN. For example, when the display panel PN is an inorganic light emitting display panel, the light emitting diode can be a light emitting diode (LED) or a micro light emitting diode (micro LED).

The active area AA also includes a plurality of signal lines which transmits various signals to the sub pixels SP is disposed. For example, the signal lines can include a plurality of data lines DL which supplies a data voltage to each sub pixel SP and a plurality of scan lines SL which supplies a gate voltage to each sub pixel SP. As shown in FIG. 1, the scan lines SL extends in one direction in the active area AA an are connected to the sub pixels SP, and the data lines DL extends in a direction different from the one direction in the active area AA and are connected to the sub pixels SP. In addition, the active area AA includes low potential power line, a high potential power line, and various other signal lines can be further disposed, but are not limited thereto.

Further, in the non-active area NA, images are not displayed, and a link line which transmits a signal to the sub pixel SP of the active area AA, a pad electrode, or a driving IC, such as a gate driver IC or a data driver IC, can be disposed. Also, the display panel PN includes a plurality of pixels each of which is formed by a plurality of sub pixels SP. Each sub pixel SP includes a light emitting diode LED and a pixel circuit so each of sub pixel SP can independently emit light. In addition, one pixel can include a first sub pixel, a second sub pixel, and a third sub pixel. For example, one pixel can be configured by one pair of first sub pixels, one pair of second sub pixels, and one pair of third sub pixels. In addition, each first sub pixel is a red sub pixel, each second sub pixel is a green sub pixel, and each third sub pixel is a blue sub pixel, but it is not limited thereto. In other examples, one pixel may be configured by one pair of first sub pixels, one pair of second sub pixels, one pair of third sub pixels, and one pair of fourth sub pixels with each fourth sub pixel is a white sub pixel, a yellow sub pixel, a magenta sub pixel, or a pair of differently shaded/lighter blue pixels.

Also, a plurality of light emitting diodes can be disposed in the sub pixels SP. For example, the light emitting diodes can include a first light emitting diode, a second light emitting diode, and a third light emitting diode. The first sub pixel can include the first light emitting element, the second sub pixel can include the second light emitting element, and the third sub pixel can include the third light emitting element. In addition, the first light emitting diode can be a red light emitting diode, the second light emitting diode can be a green light emitting diode, and the third light emitting diode can be a blue light emitting diode.

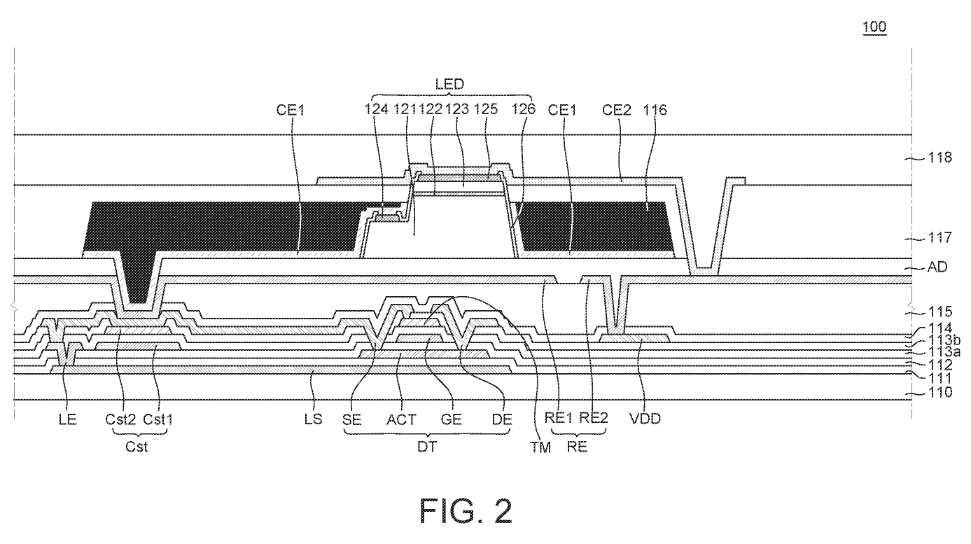

Next, FIG. 2 is an enlarged cross-sectional view of a sub pixel SP of a display device 100 according to an embodiment of the present disclosure. As shown in FIG. 2, the sub pixel SP of the the display device 100 includes a substrate 110, a buffer layer 111, a gate insulating layer 112, a first interlayer insulating layer 113a, a second interlayer insulating layer 113b, a passivation layer 114, a first planarization layer 115, an adhesive layer AD, a second planarization layer 116, a third planarization layer 117, a fourth planarization layer 118, a driving transistor DT, a light emitting diode LED, a reflective electrode RE, a light shielding layer LS, an auxiliary electrode LE, a first connection electrode CE1, a second connection electrode CE2, a capacitor Cst, and an intermediate electrode TM.

First, the substrate 110 is a component for supporting various components included in the display device 100 and can be formed of an insulating material. For example, the substrate 110 can be formed of glass or resin. Further, the substrate 110 can include a polymer or plastics or can be formed of a material having flexibility.

In addition, as shown, the light shielding layer LS can be disposed in each sub pixel SP on the substrate 110. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current. The light shielding layer LS can include a conductive material such as copper (Cu), aluminum (Al), molybdenum (Mo), nickel (Ni), titanium (Ti), chrome (Cr), or an alloy thereof, but is not limited thereto.

Further, the buffer layer 111 can be disposed on the substrate 110 and the light shielding layer LS. In particular, the buffer layer 111 can reduce permeation of moisture or impurities through the substrate 110. For example, the buffer layer 111 can be a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

In addition, the driving transistor DT can be disposed on the buffer layer 111 and as shown includes an active layer ACT, a gate electrode GE, a source electrode SE, and a drain electrode DE. Further, the active layer ACT can be disposed on the buffer layer 111 and be formed of a semiconductor material, such as an oxide semiconductor, amorphous silicon, or polysilicon, but is not limited thereto.

In addition, the gate insulating layer 112 can be disposed on the active layer ACT, insulates the active layer ACT from the gate electrode GE and can be a single layer or a double layer of silicon oxide (SiOx) or silicon nitride (SiNx), but is not limited thereto. The gate electrode GE can be disposed on the gate insulating layer 112 and can include a conductive material, such as copper (Cu), aluminum (Al), molybdenum (Mo), nickel (Ni), titanium (Ti), chrome (Cr), or an alloy thereof, but is not limited thereto. The gate electrode GE also can be composed of multipe layers. For example, the gate electrode GE can be composed of a bottom layer of molybdenum (Mo), a middle laayer of copper (Cu) or aluminum (Al), and a top layer of titanium (Ti).

In addition, first interlayer insulating layer 113a and the second interlayer insulating layer 113b can be disposed on the gate electrode GE and include contact holes through which the source electrode SE and the drain electrode DE are connected to the active layer ACT. In particular, the first interlayer insulating layer 113a and the second interlayer insulating layer 113b are insulating layers for protecting a component below the first interlayer insulating layer 113a and the second interlayer insulating layer 113b and can be a single layer or a double layer of silicon oxide (SiOx) or silicon nitride (SiNx), but are not limited thereto.

Further, the source electrode SE and the drain electrode DE which are electrically connected to the active layer ACT can be disposed on the second interlayer insulating layer 113b. Also, the source electrode SE and the drain electrode DE can include a conductive material, such as copper (Cu), aluminum (Al), molybdenum (Mo), nickel (Ni), titanium (Ti), chrome (Cr), an alloy thereof, or of multipe layers of different conductive materials, but are not limited thereto.

In addition, the present specification describes the first interlayer insulating layer 113a and the second interlayer insulating layer 113b. In other words, a plurality of insulating layers are disposed between the gate electrode GE and the source electrode SE and the drain electrode DE. However, only one insulating layer can be disposed between the gate electrode GE and the source electrode SE and the drain electrode DE, and the present disclosure is not limited thereto. Further, the pixel circuit can also include a switching transistor, a sensing transistor, and an emission control transistor, in addition to the driving transistor DT, but is not limited thereto.

In addition, the intermediate electrode TM can be disposed between the first interlayer insulating layer 113a and the second interlayer insulating layer 113b. As shown in FIG. 2, the intermediate electrode TM is disposed to overlap the gate electrode GE of the driving transistor DT with the first interlayer insulating layer 113a therebetween to form a capacitor together with the gate electrode GE of the driving transistor DT, but is not limited thereto. The intermediate electrode TM can also include a conductive material such as copper (Cu), aluminum (Al), molybdenum (Mo), nickel (Ni), titanium (Ti), chrome (Cr), an alloy thereof, or of multipe layers of different conductive materials, but is not limited thereto.

In addition, the auxiliary electrode LE can be disposed on the gate insulating layer 112 and electrically connects the light shielding layer LS below the buffer layer 111 to any one of the source electrode SE of the driving transistor DT and the drain electrode DE of the driving transistor DT on the second interlayer insulating layer 113b. For example, the light shielding layer LS can be electrically connected to any one of the source electrode SE or the drain electrode DE of the driving transistor DT through the auxiliary electrode LE so as not to operate as a floating gate. Therefore, fluctuation of a threshold voltage of the driving transistor DT caused by the floated light shielding layer LS can be minimized. Even though in the drawing, the light shielding layer LS is connected to the source electrode SE of the driving transistor DT, the light shielding layer LS can also be connected to the drain electrode DE of the driving transistor DT, but is not limited thereto.

Further, the auxiliary electrode LE can be formed of the same material or materials as the gate electrode GE, but is not limited thereto. The auxiliary electrode LE can include a conductive material, such as copper (Cu), aluminum (Al), molybdenum (Mo), nickel (Ni), titanium (Ti), chrome (Cr), an alloy thereof, or of multipe layers of different conductive materials, but is not limited thereto.

As shown, the capacitor Cst can be disposed on the gate insulating layer 112. In particular, as shown in FIG. 2, the capacitor Cst can include a first capacitor electrode Cst1 and a second capacitor electrode Cst2. As shown, the first capacitor electrode Cst1 can be disposed on the gate insulating layer 112, disposed on the same layer as the gate electrode GE and the auxiliary electrode LE and can be formed of the same material or materials as the gate electrode GE and the auxiliary electrode LE, but is not limited thereto. The first capacitor electrode Cst1 can include a conductive material, such as copper (Cu), aluminum (Al), molybdenum (Mo), nickel (Ni), titanium (Ti), chrome (Cr), an alloy thereof, or of multipe layers of different conductive materials, but is not limited thereto.

In addition, the second capacitor electrode Cst2 can be disposed on the first interlayer insulating layer 113a, disposed on the same layer as the intermediate electrode TM and can be formed of the same material or materials as the intermediate electrode TM, but is not limited thereto. The second capacitor electrode Cst2can include a conductive material, such as copper (Cu), aluminum (Al), molybdenum (Mo), nickel (Ni), titanium (Ti), chrome (Cr), an alloy thereof, or of multipe layers of different conductive materials, but is not limited thereto. The second capacitor electrode Cst2 can be disposed to overlap the first capacitor electrode Cst1 with the first interlayer insulating layer 113a therebetween. The second capacitor electrode Cst2 can also be connected to the source electrode SE of the driving transistor DT.

In addition, power line VDD can be disposed on the second interlayer insulating layer 113b and is electrically connected to the light emitting diode LED together with the driving transistor DT to allow the light emitting diode LED to emit light. For example, the power line VDD can be a high potential power line, but is not limited thereto. As shown in FIG. 2, the power line VDD is disposed on the same layer as the source electrode SE and the drain electrode DE and is formed of the same material as the source electrode SE and the drain electrode DE, but is not limited thereto. The power line VDD can also a conductive material such as copper (Cu), aluminum (Al), molybdenum (Mo), nickel (Ni), titanium (Ti), chrome (Cr), an alloy thereof, or of multipe layers of different conductive materials, but is not limited thereto.

Further, the passivation layer 114 can be disposed on the driving transistor DT and the power line VDDand protects the driving transistor DT and the power line VDD from permeation of moisture or impurity. For example, the passivation layer 114 can be a single layer or a double layer of silicon oxide (SiOx) or silicon nitride (SiNx), but is not limited thereto. However, the passivation layer 114 can be omitted depending on a type of substrate 110 or a type of transistor.

Further, the first planarization layer 115 can be disposed on the passivation layer 114 and planarizes an upper portion of the substrate 110 on which the driving transistor DT is disposed. The first planarization layer 115 can also be a single layer or a double layer, and for example, can be formed of photoresist or an acrylic-based organic material, but is not limited thereto.

As shown in FIG. 2, a plurality of reflective electrodes RE are spaced apart from each otherand disposed on the first planarization layer 115. In addition, the reflective electrodes RE electrically connect the light emitting diode LED to the power line VDD and the driving transistor DT and can serve as a reflective plate which reflects light emitted from the light emitting diode LED to the top of the light emitting diode LED. The reflective electrodes RE can include a conductive material having an excellent reflecting property to reflect light emitted from the light emitting diode LED toward the top of the light emitting diode LED. Therefore, the reflective electrodes RE can include various conductive layers in consideration of a light reflection efficiency and a resistance. For example, a reflective electrode RE can use an opaque conductive layer, such as silver (Ag), aluminum (Al), molybdenum (Mo), titanium (Ti), or an alloy thereof, and a transparent conductive layer, such as indium tin oxide (ITO), but the structure and the material of the reflective electrode RE are not limited thereto. For instance, the reflective electrode RE may include multipe layers of different metal materials, or of a combination of include multipe layers of different metal materials capped by indium tin oxide (ITO).

In addition, as shown in FIG. 2, the reflective electrodes RE can include a first reflective electrode RE1 and a second reflective electrode RE2. In particular, the first reflective electrode RE1 can electrically connect the driving transistor DT and the light emitting diode LED. The first reflective electrode RE1 can be connected to the source electrode SE or the drain electrode DE of the driving transistor DT through contact holes formed in the passivation layer 114 and the first planarization layer 115. Further, the first reflective electrode RE1 can be electrically connected to the first electrode 124 of the light emitting diode LED through a first connection electrode CE1.

Also, the second reflective electrode RE2 electrically connects the power line VDD and the light emitting diode LED. In particular, the second reflective electrode RE2 can be connected to the power line VDD through a contact hole formed in the passivation layer 114 and the first planarization layer 115 and can be electrically connected to the second electrode 125 of the light emitting diode LED through a second connection electrode CE2 to be described below.

In addition, the adhesive layer AD is formed on the front surface of the substrate 110 on the reflective electrodes RE to fix the light emitting diodes LED disposed on the adhesive layer AD. The adhesive layer AD can be formed of a photo curable adhesive material or thermo-setting adhesive material which is cured by heat or light. For example, the adhesive layer AD can be formed of an acrylic-based material including a photoresist, but is not limited thereto.

In a number of embodiments, including embodiments where a thermo-setting adhesive material is used, the adhesive layer AD can include a pigment, such as a white/reflective pigment, such as titanium oxide (TiO₂). As used in this example, “reflective” refers to reflecting more light than is absorbed. Also, the adhesive layer AD can include a black pigment, such as carbon particles. In yet other embodiments, the adhesive layer AD can include particles designed to scatter light, and provide the scattered light back into individual light emitting diodes LED.

Further, the light emitting diodes LED can be disposed in each sub pixel SP on the adhesive layer AD. The light emitting diodes LED is elements which emit light by a current and can include light emitting diodes LED which emit red light, green light, and blue light and implement various colored light including white by a combination thereof. For example, the light emitting diodes LED can be light emitting diodes (LED) or a micro LEDs, but is not limited thereto.

As shown, each of the light emitting diodes LED can include a first semiconductor layer 121, an emission layer 122, a second semiconductor layer 123, a first electrode 124, a second electrode 125, and an encapsulation film 126. The first semiconductor layer 121 can be disposed on the adhesive layer AD and the second semiconductor layer 123 can be disposed on the first semiconductor layer 121. Also, the first semiconductor layer 121 and the second semiconductor layer 123 can be layers formed by doping n-type and p-type impurities into a specific material. For example, the first semiconductor layer 121 and the second semiconductor layer 123 can be layers doped with n-type and p-type impurities into a material such as gallium nitride (GaN), indium aluminum phosphide (InAlP), or gallium arsenide (GaAs). Further, the p-type impurity can be magnesium (Mg), zinc (Zn), and beryllium (Be), and the n-type impurity can be silicon (Si), germanium (Ge), and tin (Sn), but is not limited thereto.

As shown in FIG. 2, a part of the first semiconductor layer 121 can be disposed to outwardly protrude from the second semiconductor layer 123. Also, a top surface of the first semiconductor layer 121 is formed by a part overlapping a bottom surface of the second semiconductor layer 123 and a part disposed at an outside of the bottom surface of the second semiconductor layer 123. The light emitting diode LED can be a lateral light emitting diode LED. However, sizes and shapes of the first semiconductor layer 121 and the second semiconductor layer 123 can be modified in various forms, but are not limited thereto.

For example, the first semiconductor layer 121 can protrude outwardly from the second semiconductor layer 123 in some direction. The first semiconductor layer 121 can also protrude to the outside of the second semiconductor layer 123 from a part of the edge of the second semiconductor layer 123. In addition, a part of the first semiconductor layer 121 can protrude outwardly from the second semiconductor layer 123 in a specific direction.

As shown in FIG. 2, the emission layer 122 can be disposed between the first semiconductor layer 121 and the second semiconductor layer 123 and is supplied with holes and electrons from the first semiconductor layer 121 and the second semiconductor layer 123 to emit light. The emission layer 122 can be formed by a single layer or a multi-quantum well (MQW) structure, and for example, can be formed of indium gallium nitride (InGaN) or gallium nitride (GaN), but is not limited thereto.

In addition, the first electrode 124 can be disposed on the first semiconductor layer 121 and electrically connects the driving transistor DT and the first semiconductor layer 121. In this instance, the first semiconductor layer 121 is doped with an n-type impurity and the first electrode 124 can be a cathode. The first electrode 124 can also be disposed on a top surface of the first semiconductor layer 121 which is exposed from the emission layer 122 and the second semiconductor layer 123. Also, the first electrode 124 can include a conductive material, for example, a transparent conductive material, such as indium tin oxide (ITO) or indium zinc oxide (IZO) or an opaque conductive material, such as titanium (Ti), gold (Au), silver (Ag), copper (Cu), an alloy thereof, or multiple conductive materials, but is not limited thereto.

Further, the first electrode 124 can be disposed to be closer to the substrate 110 than the emission layer 122. For example, the first semiconductor layer 121 can have a thickness in an area overlapping the emission layer 122 larger than a thickness in an area overlapping the first electrode 124. Accordingly, in the cross-sectional view, the first electrode 124 and the emission layer 122 are disposed on different planes.

In addition, the second electrode 125 can be disposed on the second semiconductor layer 123 and in particular be disposed on the top surface of the second semiconductor layer 123. In addition, the second semiconductor layer 123 is disposed on the first semiconductor layer 121 so the second electrode 125 disposed on the top surface of the second semiconductor layer 123 can be disposed to be higher than the first electrode 124 disposed on the top surface of the first semiconductor layer 121. Also, the second electrode 125 is an electrode which electrically connects the power line VDD and the second semiconductor layer 123. In this instance, the second semiconductor layer 123 is a semiconductor layer doped with a p-type impurity and the second electrode 125 can be an anode. The second electrode 125 can include a conductive material, for example, a transparent conductive material, such as indium tin oxide (ITO) or indium zinc oxide (IZO) or an opaque conductive material, such as titanium (Ti), gold (Au), silver (Ag), copper (Cu), an alloy thereof, or multiple conductive materials, but is not limited thereto.

Next, the encapsulation film 126 covers the first semiconductor layer 121, the emission layer 122, the second semiconductor layer 123, the first electrode 124, and the second electrode 125. In particular, the encapsulation film 126 is formed of an insulating material to protect the first semiconductor layer 121, the emission layer 122, and the second semiconductor layer 123. Further, in the encapsulation film 126, respective contact holes, which expose the first electrode 124 and the second electrode 125 are formed to electrically connect a first connection electrode CE1 and a second connection electrode CE2 to the first electrode 124 and the second electrode 125 respectively to be formed after the contact holes are formed.

In addition, the adhesive layer AD and the light emitting diode LED can be disposed to be in direct contact with the first connection electrode CE1 on the adhesive layer AD and the light emitting diode LED. Also, the first connection electrode CE1 is disposed in each sub pixel SP to electrically connect the light emitting diode LED and the driving transistor DT. In particular, the first connection electrode CE1 can be connected to the first reflective electrode RE1 through the contact hole formed in the adhesive layer AD. Accordingly, the first connection electrode CE1 can be electrically connected to any one of the source electrode SE and the drain electrode DE of the driving transistor DT through the first reflective electrode RE1. For example, the first connection electrode CE1 can connect the first electrode 124 of the light emitting diode LED to the source electrode SE of the driving transistor DT, but it is not limited thereto.

In addition, the first connection electrode CE1 can include a reflective conductive material. In particular, the first connection electrode CE1, for example, can be formed of an opaque reflective conductive material, such as copper (Cu), aluminum (Al), molybdenum (Mo), nickel (Ni), titanium (Ti), chrome (Cr), an alloy thereof, or by mutipe conductive materials.

Also, as shown in FIG. 2, the first connection electrode CE1 can be disposed to cover a part of a lower side surface of the light emitting diode LED while being in direct contact with the light emitting diode LED. For example, the first connection electrode CE1 can be disposed to extend from a top surface of the first electrode 124 to cover the encapsulation film 126 disposed on a lower edge of the light emitting diode LED. As shown, the first connection electrode CE1 can cover a side surface of the first semiconductor layer 121 disposed below the emission layer 122. In addition, the first connection electrode CE1 can be disposed to cover the side surface of the first semiconductor layer 121, but not to cover the side surface of the emission layer 122. Ergo,the top of the first connection electrode CE1 can be located between a top surface of the first electrode 124 and a bottom surface of the emission layer 122. Further, the first connection electrode CE1 extends from a lower side surface of the light emitting diode LED to be in contact with the top surface of the adhesive layer AD.

In addition, the second planarization layer 116 can be disposed on the first connection electrode CE1 and the light emitting diode LED to cover a part of side surfaces of the light emitting diodes LED to fix and protect the light emitting diodes LED. The second planarization layer 116 can also be disposed on the first connection electrode CE1 to cover the side surface of the light emitting diode LED. In addition, the second planarization layer 116 can have a thickness smaller than a thickness of the light emitting diode LED. For example, the second planarization layer 116 can cover a side surface of the first semiconductor layer 121 disposed below the emission layer 122.

Further, the second planarization layer 116 can also be disposed above the first electrode 124 and can cover a top surface of the first connection electrode CE1 disposed above the first electrode 124. Accordingly, the second planarization layer 116 can be disposed to overlap the first electrode 124 of the light emitting diode LED and a part of a side surface of the light emitting diode LED. Further, the second planarization layer 116 can be disposed to cover the side surface of the first semiconductor layer 121, but not to cover the side surface of the emission layer 122. Ergo, the top surface of the second planarization layer 116 can be located between the top surface of the first electrode 124 and the bottom surface of the emission layer 122.

In addition, the top surface of the second planarization layer 116 can expose one surface of the first connection electrode CE1 disposed on the side surface of the light emitting diode LED. For example, referring to FIG. 2, the top surface of the second planarization layer 116 is disposed on the same plane as a surface of the first connection electrode CE1 disposed at the top, among the first connection electrodes CE1. Accordingly, the surface of the first connection electrode CE1 disposed at the top, among the first connection electrodes CE1, can be exposed by the second planarization layer 116.

Also, as shown in FIG. 2, the top surface of the second planarization layer 116 and the top of the first connection electrode CE1 can be disposed to be lower than the bottom surface of the emission layer 122 of the light emitting diode LED. Accordingly, light output from the emission layer 122 of the light emitting diode LED is not be restricted by the first connection electrode CE1. Therefore, the first connection electrode CE1 is disposed not to restrict the light path of the light emitting diode LED, thereby increasing a luminous efficiency of the light emitting diode LED. However, the present disclosure is not limited thereto and the top surface of the second planarization layer 116 and the top of the first connection electrode CE1 can be disposed to be higher than the bottom surface of the emission layer 122 of the light emitting diode LED depending on the position of the emission layer 122 in the light emitting diode LED and the lateral structure of the light emitting diode LED.

In addition, the second planarization layer 116 can expose a side surface of the first connection electrode CE1 disposed on the adhesive layer AD. For example, referring to FIG. 2, a width of the bottom surface of the second planarization layer 116 and a width of the top surface of the first connection electrode CE1 can be equal and the side surface of the second planarization layer 116 and the side surface of the first connection electrode CE1 can be disposed on the same plane. Therefore, in the plan view, a planar shape of the second planarization layer 116 and a planar shape of the first connection electrode CE1 can be the same and the side surface of the first connection electrode CE1 can be exposed by the second planarization layer 116.

Also, the second planarization layer 116 can include a black material such as a black component having a high light absorptance. Accordingly, the second planarization layer 116 can suppress color mixture which can be caused between the light emitting diodes LED which emit different color light and suppress external light reflection.

Also, the third planarization layer 117 is disposed on the adhesive layer AD, the first connection electrode CE1, and the second planarization layer 116 and to cover a part of side surfaces of the light emitting diodes LED to fix and protect the light emitting diodes LED. Further, the third planarization layer 117 is disposed between the second planarization layer 116 and the second connection electrode CE2 to planarize an upper portion of the second planarization layer 116 and a lower portion of the second connection electrode CE2.

In addition, the third planarization layer 117 covers the upper portion of the second planarization layer 116 and covers a part of the upper side surface of the light emitting diode LED exposed by the second planarization layer 116. As shown, a top surface of the third planarization layer 117 is disposed to be higher than the emission layer 122 of the light emitting diode LED and can be disposed to be equal to or lower than the top surface of the second semiconductor layer 123. For example, a top surface of the third planarization layer 117 can be disposed between the top surface of the emission layer 122 and the top surface of the second semiconductor layer 123 or on the same plane as the top surface of the second semiconductor layer 123.

Further, the third planarization layer 117 extends from the upper portion of the second planarization layer 116 to cover the side surface of the second planarization layer 116 and the side surface of the first connection electrode CE1. In addition, the third planarization layer 117 can cover the top surface of the adhesive layer AD disposed at the outside of the second planarization layer 116.

Also, the third planarization layer 117 can be a single layer or a double layer. The third planarization layer 117, for example, can also be formed of a photoresist or an acrylic-based organic material, but is not limited thereto.

In addition, as shown, the second connection electrode CE2 can be disposed on the third planarization layer 117 for electrically connecting the light emitting diode LED and the power line VDD. Also, the second connection electrode CE2 can be connected to the second reflective electrode RE2 through the contact hole formed in the third planarization layer 117 and the adhesive layer AD. Accordingly, the second connection electrode CE2 can be electrically connected to the power line VDD through the second reflective electrode RE2. For example, the second connection electrode CE2 can connect the second electrode 125 of the light emitting diode LED to the power line VDD, but it is not limited thereto.

In addition, the second connection electrode CE2 can be formed of a material different from a material of the first connection electrode CE1. For example, the second connection electrode CE2 can be formed of, for example, a transparent conductive material, such as indium tin oxide (ITO) or indium zinc oxide (IZO).

As shown, the fourth planarization layer 118 can be disposed on the third planarization layer 117 and the second connection electrode CE2. In particular, the fourth planarization layer 118 planarizes an upper portion of the substrate 110 on which the light emitting diode LED is disposed to fix and protect the light emitting diode LED. Therefore, the fourth planarization layer 118 can also be referred to as a protection layer or a capping layer, but is not limited thereto. Also, the fourth planarization layer 118 can be a single layer or a double layer, and for example, can be formed of photoresist or an acrylic-based organic material, but is not limited thereto.

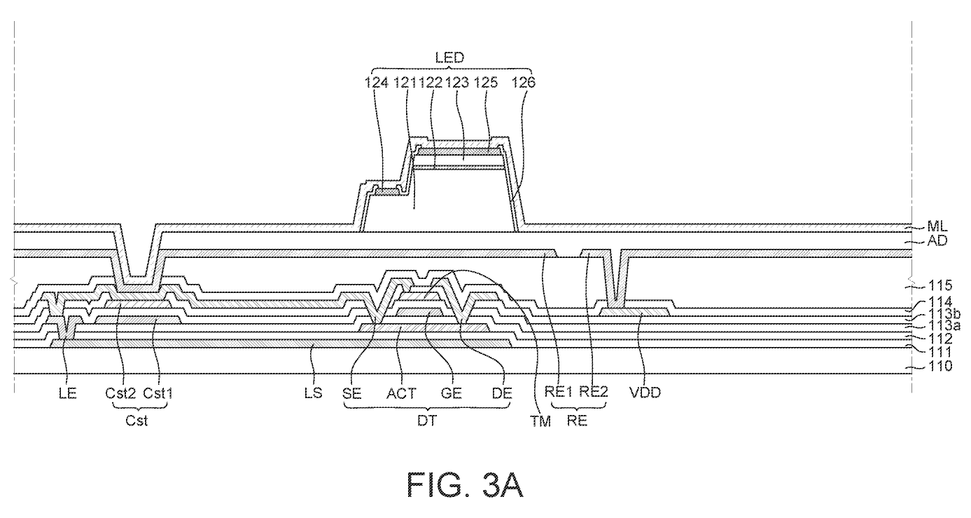

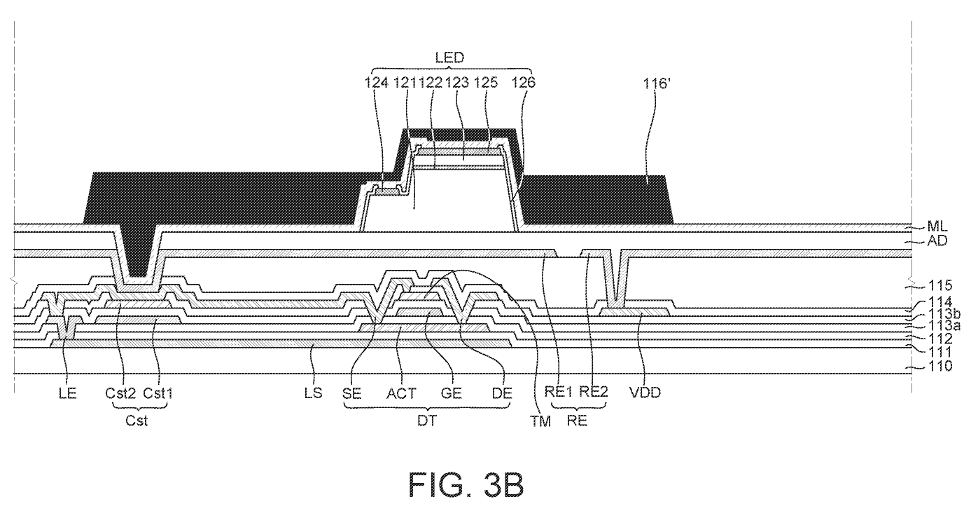

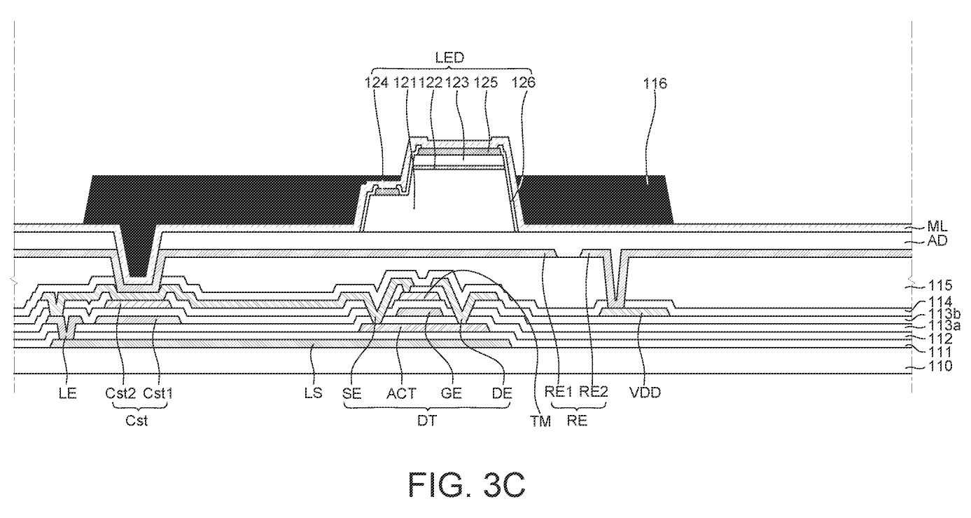

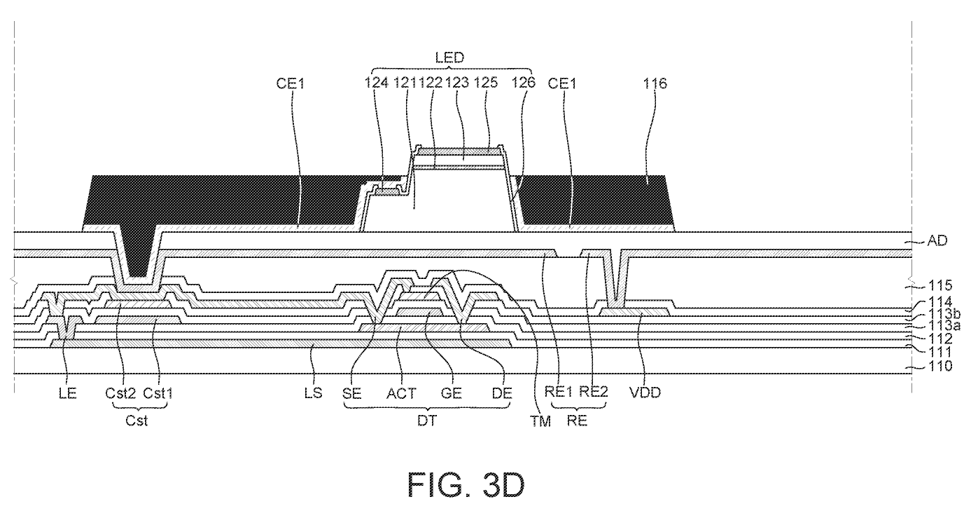

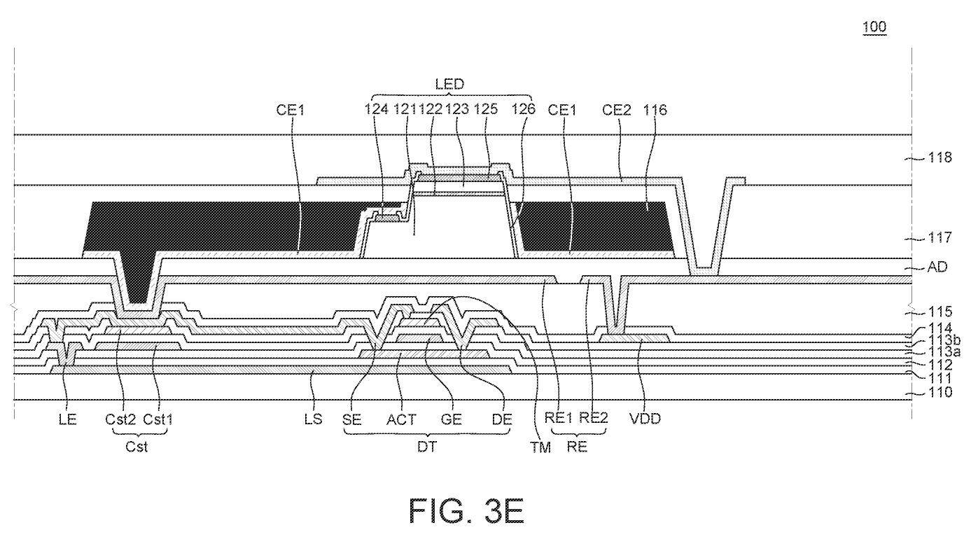

Hereinafter, a manufacturing method of a display device according to an embodiment of the present disclosure will be described with reference to FIGS. 3A to 3E together. First, referring to FIG. 3A, a light emitting diode LED is disposed on an adhesive layer AD and a metal layer ML is formed on the adhesive layer AD to cover the light emitting diode LED. In addition, the metal layer ML can be disposed on the entire substrate 110 and covers a top surface of the adhesive layer AD and a top surface and a side surface of the light emitting diode LED. Further, the metal layer ML covers a surface of an encapsulation film 126 of the light emitting diode LED and can cover the first electrode 124 and the second electrode 125 exposed through a contact hole of the encapsulation film 126. Also, the metal layer ML can cover the first reflective electrode RE1 exposed through contact holes of the passivation layer 114 and the first planarization layer 115.

Referring to FIG. 3B, an initial second planarization layer 116' including a photo sensitive material is formed on the metal layer ML. In particular, the initial second planarization layer 116' is formed to cover a partial area of the metal layer ML. For example, the initial second planarization layer 116' can be formed to cover the metal layer ML which extends to cover from the contact holes of the passivation layer 114 and the first planarization layer 115 through which the source electrode SE of the driving transistor DT is exposed to a top surface and a side surface of the light emitting diode LED.

Referring to FIG. 3C, a part of the initial second planarization layer 116' is removed to form a second planarization layer 116. For example, the initial second planarization layer 116' can be subjected to an ashing process to remove a part of the initial second planarization layer 116' which covers an upper portion of the light emitting diode LED. In particular, the ashing process is performed to allow the second planarization layer 116 to cover the top surface of the metal layer ML on the first electrode 124 and a part of the metal layer ML disposed on a lower side surface of the light emitting diode LED, but expose a top surface of the metal layer ML on the second electrode 125 and a part of the metal layer ML disposed on an upper side surface of the light emitting diode LED.

Next, referring to FIG. 3D, the metal layer ML disposed in an area which does not overlap the second planarization layer 116 is removed to form the first connection electrode CE1. For example, a photo process can be performed and the second planarization layer 116 can be used as a mask of the first connection electrode CE1. Accordingly, the metal layer ML which covers the second electrode 125 and the metal layer ML which covers the upper side surface of the light emitting diode LED above the second planarization layer 116 is removed to form the first connection electrode CE1.

Next, referring to FIG. 3E, the third planarization layer 117, the second connection electrode CE2, and the fourth planarization layer 118 are sequentially formed on the first connection electrode CE1. The third planarization layer 117 is formed to cover a part of an upper side surface of the light emitting diode LED exposed by the second planarization layer 116. In addition, the third planarization layer 117 is formed to expose the second electrode 125. Next, the second connection electrode CE2 and the fourth planarization layer 118 are formed on the third planarization layer 117. The second connection electrode CE2 is formed to cover a top surface of the second electrode 125 exposed from the third planarization layer 117 and extends on the second electrode 125 to be formed on the third planarization layer 117. Further, the second connection electrode CE2 can cover the second reflective electrode RE2 exposed from the contact hole of the third planarization layer 117. Thereafter, the fourth planarization layer 118 which covers a top surface of the second connection electrode CE2 is formed.

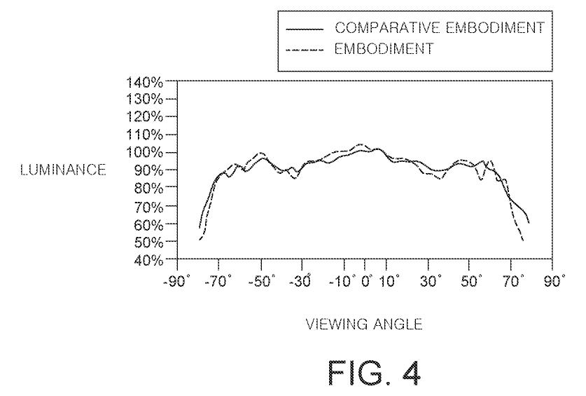

Hereinafter, a luminance according to a viewing angle of a display device 100 according to an embodiment of the present disclosure will be identified with reference to FIG. 4. In particular, FIG. 4 is a graph illustrating a luminance according to a viewing angle of a display device according to an embodiment of the present disclosure. The example shown in FIG. 4 is a display device 100 according to an embodiment of the present disclosure and a different display device according to a comparative embodiment where a first connection electrode CE1 is formed of a transparent conductive material.

In FIG. 4, the X-axis indicates a viewing angle and the Y-axis indicates a luminance. Further, in the comparative embodiment, a luminance in the front direction, that is, at a viewing angle of 0° is 100% and a relative luminance thereof is denoted with a reference symbol %.

Referring to FIG. 4, it is confirmed in both the comparative embodiment and embodiment of the present disclosure, in the front direction and the lateral direction of 50° to 70°, high luminance can be obtained. Further, it is confirmed a luminance of the embodiment of the present disclosure is approximately 108% and the front luminance is increased by approximately 8% as compared with the comparative embodiment at a viewing angle of 0.

In addition, the second connection electrode CE2 includes a transparent conductive material, but the first connection electrode CE1 includes a reflective conductive material. Accordingly, among light emitted from the light emitting diode LED, light directed to a direction in which the first connection electrode CE1 is disposed can be reflected by the first connection electrode CE1. For example, among light emitted from the light emitting diode LED, light directed to a direction in which the side surface of the first semiconductor layer 121 and the first electrode 124 are disposed can be reflected by the first connection electrode CE1. Accordingly, light reflected by the first connection electrode CE1 is reflected again by the first reflective electrode RE1 disposed below the light emitting diode LED to travel to an area which is not covered by the first connection electrode CE1. Accordingly, light reflected by the first connection electrode CE1 and the first reflective electrode RE1 travels to a direction in which the second semiconductor layer 125 of the light emitting diode LED is disposed and can pass through the second electrode 125 and the second connection electrode CE2 formed of a transparent conductive material. Accordingly, in the display device 100 according to the embodiment of the present disclosure, as compared with an example where both the first connection electrode CE1 and the second connection electrode CE2 are formed of a transparent conductive material, the front luminance can be improved. Accordingly, as the front luminance of the display device 100 is improved, low-power driving can be possible.

Further, the second planarization layer 116 covering the side surface of the light emitting diode LED includes a black material. Accordingly, the second planarization layer 116 fixes the light emitting diode LED and insulates the light emitting diode LED and peripheral components and suppresses the color mixture and external light reflection. Therefore, in the display device 100 according to the embodiment of the present disclosure a black matrix, for example, a black bank is not separately used above the light emitting diode LED. Therefore, the thickness of the display device 100 is reduced and a process of forming the black bank and the number of masks used for the process can be reduced. Accordingly, process optimization can be implemented by reducing the process cost and the time.

Further, the second planarization layer 116 covering the side surface of the light emitting diode LED is used as a mask of the first connection electrode CE1. For example, the second planarization layer 116 can be formed to correspond to the first connection electrode CE1 to pattern the first connection electrode CE1. Accordingly, a photo process or a mask process for forming the first connection electrode CE1 is not performed to reduce a process cost and a time and thus the process optimization can be implemented.

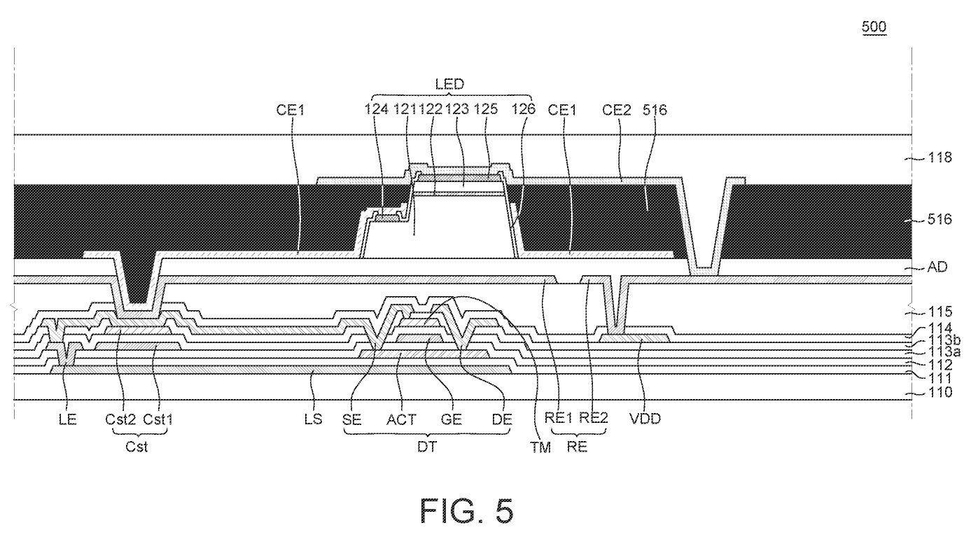

Next, FIG. 5 is an enlarged cross-sectional view of a display device according to another embodiment of the present disclosure. A display device 500 of FIG. 5 is different from the display device 100 of FIGS. 1 to 4 where a third planarization layer 117 is not disposed and only a second planarization layer 516 is different, but the other configurations are substantially the same, so a redundant description will be omitted.

Referring to FIG. 5, a second planarization layer 516 is disposed on the first connection electrode CE1 and the light emitting diode LED. The second planarization layer 516 is disposed on the first connection electrode CE1 to cover the side surface of the light emitting diode LED while being in direct contact with the side surface of the light emitting diode LED. In addition, a top surface of the second planarization layer 516 is disposed to be higher than the emission layer 122 and can be disposed to be equal to or lower than the top surface of the second semiconductor layer 123. For example, a top surface of the second planarization layer 516 can be disposed between the top surface of the emission layer 122 and the top surface of the second semiconductor layer 123 or on the same plane as the top surface of the second semiconductor layer 123.

In addition, the second planarization layer 516 can cover a top surface of the first connection electrode CE1 disposed above the first electrode 124 while being in direct contact with the top surface of the first connection electrode CE1. Further, the second planarization layer 516 can cover a side surface of the first connection electrode CE1. For example, the second planarization layer 516 can cover a side surface of the first connection electrode CE1 disposed on the side surface of the light emitting diode LED and can cover an upper side surface of the light emitting diode LED disposed above the first connection electrode CE1. Further, the second planarization layer 516 can cover a surface of the first connection electrode CE1 disposed at the top of the first connection electrode CE1.

Also, the second planarization layer 516 can cover the side surface of the first connection electrode CE1 disposed above the adhesive layer AD while being in direct contact with the side surface of the first connection electrode CE1. For example, in the plan view, an area of the second planarization layer 516 can be larger than an area of the first connection electrode CE1. Accordingly, the second planarization layer 516 extends from the upper portion of the first connection electrode CE1 to cover the top surface of the adhesive layer AD.

In addition, the second planarization layer 516 can include a black material. Accordingly, the second planarization layer 516 can suppress color mixture which can be caused between the light emitting diodes LED which emit different color light and suppress external light reflection.

Further, a bottom surface of the second planarization layer 516 is in contact with a top surface of the first connection electrode CE1 and a top surface of the second planarization layer 516 is located lower than the top surface of the second electrode 125 and can be in contact with a bottom surface of the second connection electrode CE2. For example, the second planarization layer 516 can be formed of an insulating material to suppress the first connection electrode CE1 and the second connection electrode CE2 from being electrically connected.

In addition, the second planarization layer 516 can include a plurality of contact holes which exposes a top surface of the second reflective electrode RE2. Also, the second connection electrode CE2 can be disposed in the contact hole of the second planarization layer 516. Accordingly, the second connection electrode CE2 can be connected to the second reflective electrode RE2 through the contact holes formed in the second planarization layer 516 and the adhesive layer AD.

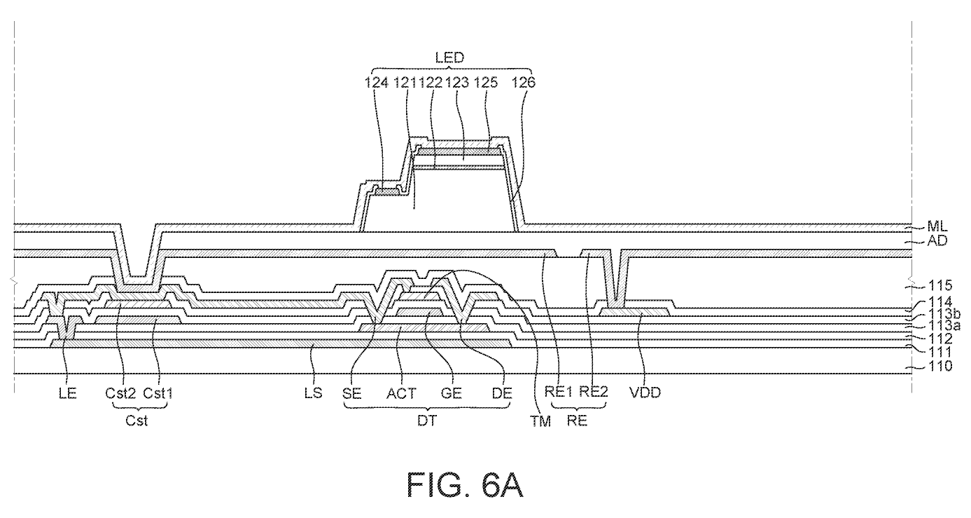

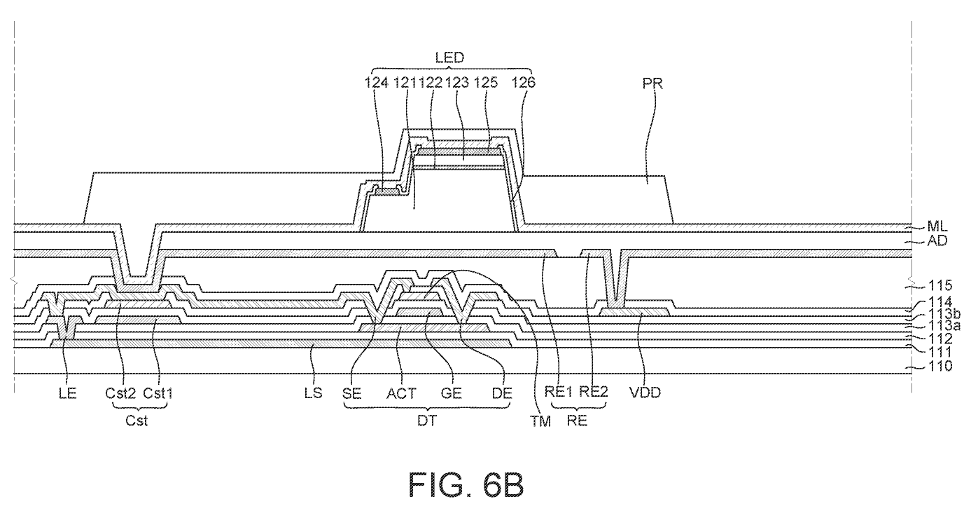

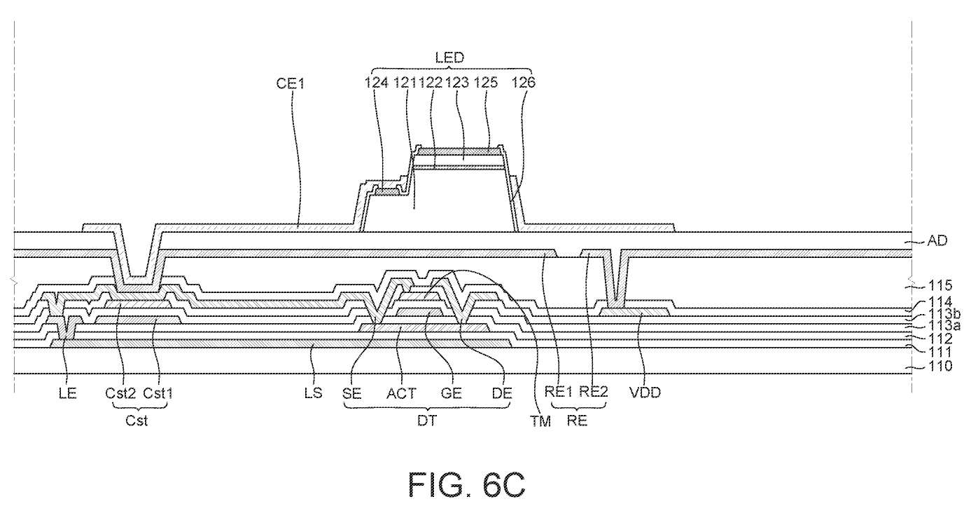

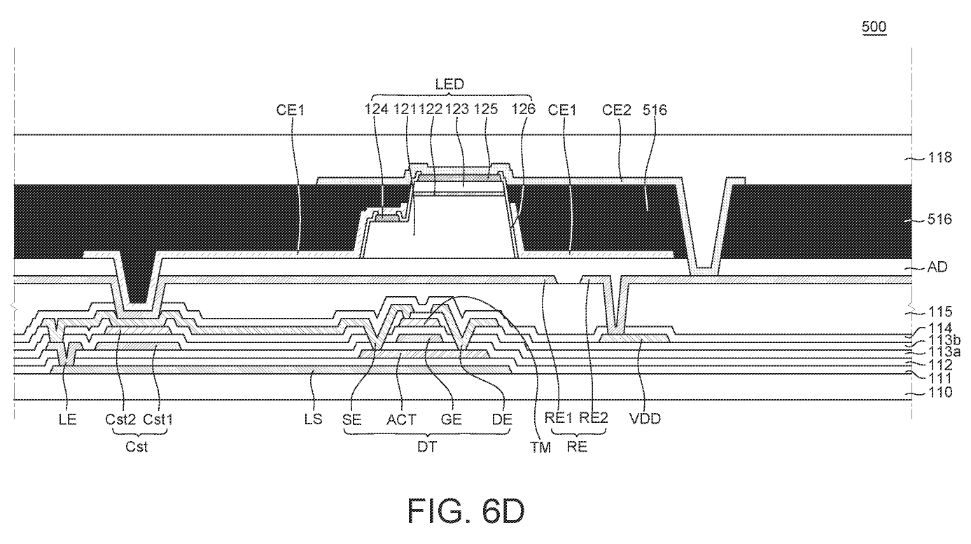

Hereinafter, a manufacturing method of a display device according to another embodiment of the present disclosure will be described with reference to FIGS. 6A to 6D together. In particular, FIGS. 6A to 6D are views for explaining a manufacturing method of a display device according to another embodiment of the present disclosure.

First, referring to FIG. 6A, a light emitting diode LED is disposed on an adhesive layer AD and a metal layer ML is formed on the adhesive layer AD to cover the light emitting diode LED. The metal layer ML is disposed on the entire substrate 110 and can cover a top surface of the adhesive layer AD and a top surface and a side surface of the light emitting diode LED. Further, the metal layer ML covers a surface of an encapsulation film 126 of the light emitting diode LED and can cover the first electrode 124 and the second electrode 125 exposed through a contact hole of the encapsulation film 126.

Referring to FIG. 6B, a photo resist PR including a photo sensitive material is formed on the metal layer ML to cover a partial area of the metal layer ML. For example, the photo resist PR can be formed to cover the metal layer ML which extends to cover from the contact holes of the passivation layer 114 and the first planarization layer 115 through which the source electrode SE of the driving transistor DT is exposed to a top surface and a side surface of the light emitting diode LED.

Referring to FIG. 6C, the photo resist PR is used as a mask of the metal layer ML to form the first connection electrode CE1. For example, the photo resist PR can be subjected to an ashing process to remove a part of the photo resist PR which covers an upper portion of the light emitting diode LED. Also, a top surface of the metal layer ML on the second electrode 125 and a part of the metal layer ML disposed on an upper side surface of the light emitting diode LED can be exposed by the ashing process. Thereafter, the first connection electrode CE1 is formed by removing the metal layer ML disposed in an area which does not overlap the photo resist PR. Next, the top surface of the first connection electrode CE1 is exposed by removing the photo resist PR.

Next, referring to FIG. 6D, the second planarization layer 516, the second connection electrode CE2, and the fourth planarization layer 118 are formed on the first connection electrode CE1. The second planarization layer 516 is formed to cover a top surface and a side surface of the first connection electrode CE1. Further, the second planarization layer 516 is formed to cover the upper side surface of the light emitting diode LED exposed from an upper portion of the first connection electrode CE1. In addition, the second planarization layer 516 is formed to expose the second electrode 125.

Next, the second connection electrode CE2 and the fourth planarization layer 118 are formed on the second planarization layer 516 to cover a top surface of the second electrode 125 exposed from the second planarization layer 516 and extends on the second electrode 125 to be formed on the second planarization layer 516. Thereafter, the fourth planarization layer 118 which covers the top surface of the second connection electrode CE2 is formed.

In the display device 500 according to another embodiment of the present disclosure, the second connection electrode CE2 includes a transparent conductive material, but the first connection electrode CE1 includes a reflective conductive material. Accordingly, light reflected from the first connection electrode CE1 and the first reflective electrode RE1 travels to the front direction of the light emitting diode LED and the front luminance of the display device 500 can be improved so low-power driving can be possible.

Further, the second planarization layer 516 covering the side surface of the light emitting diode LED includes a black material. Accordingly, the black bank is not separately requested so the thickness of the display device 500 is reduced and the number of processes and the number of masks are reduced to save the process cost and the time.

Further, a separate planarization layer is not formed above the second planarization layer 516, but the second connection electrode CE2 is disposed. Accordingly, a separate process for forming an insulating layer is not requested so not only the number of processes and the number of masks are reduced, but also the process cost and the time can be saved.

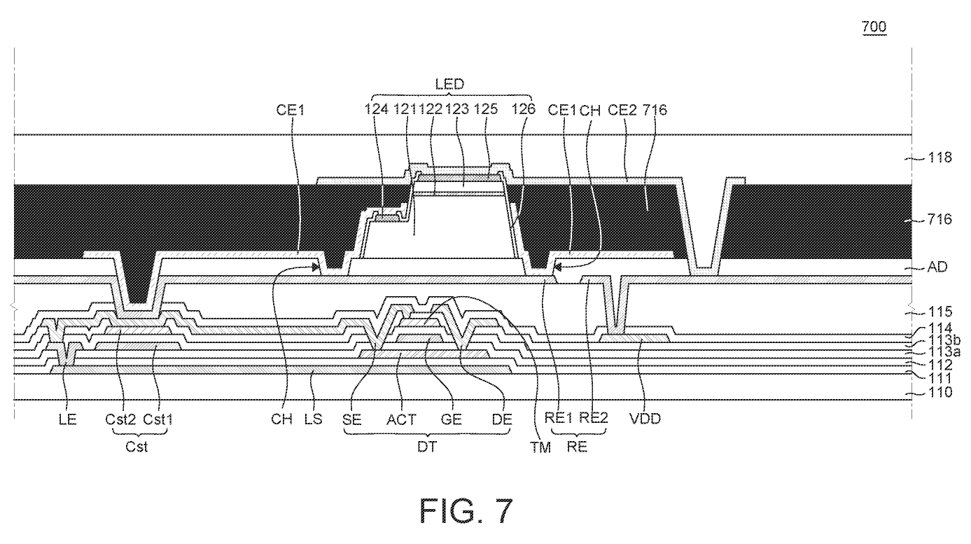

Next, FIG. 7 is an enlarged cross-sectional view of a display device according to still another embodiment of the present disclosure. As compared with the display device 500 of FIG. 5, only an adhesive layer AD, a second planarization layer 716, and a first connection electrode CE1 of a display device 700 of FIG. 7 are different, but the other configurations are substantially the same so a redundant description will be omitted.

Referring to FIG. 7, the adhesive layer AD is disposed on the reflective electrodes RE and includes a plurality of contact holes CH surrounding the light emitting diodes LED, respectively. For example, each of the contact holes CH can have a closed loop shape. In addition, each of the contact holes CH has a shape which surrounds an outer diameter of the light emitting diode LED, but is not limited thereto.

Further, the contact holes CH can expose a top surface of the first reflective electrode RE1 disposed below the adhesive layer AD. For example, the adhesive layer AD can be formed of an island shaped pattern corresponding to a shape of each of the light emitting diodes LED and a layer which is disposed at the outside of the light emitting diodes LED to surround an island shaped pattern.

Also, the light emitting diode LED and the first connection electrode CE1 are disposed on the adhesive layer AD. As shown, the first connection electrode CE1 extends from a side surface of the light emitting diode LED to cover the top surface of the adhesive layer AD. In addition, the first connection electrode CE1 can be disposed in the contact holes CH of the adhesive layer AD. Accordingly, the first connection electrode CE1 can be in contact with the top surface of the first reflective electrode RE1 in the contact holes CH of the adhesive layer AD. Also, the adhesive layer AD disposed below the light emitting diode LED can be covered by the first connection electrode CE1, the light emitting diode LED, and the first reflective electrode RE1. In other words, the adhesive layer AD disposed below the light emitting diode LED can be covered by a reflective conductive material, except for a surface which is in contact with the light emitting diode LED.

In addition, the second planarization layer 716 is disposed on the first connection electrode CE1 and the light emitting diode LED and planarizes an upper portion of the first connection electrode CE1. For example, the second planarization layer 716 can be disposed in the contact holes CH of the adhesive layer AD to planarize an upper portion of the adhesive layer AD.

In the display device 700, the second connection electrode CE2 includes a transparent conductive material, but the first connection electrode CE1 can include a reflective conductive material. Accordingly, light reflected from the first connection electrode CE1 and the first reflective electrode RE1 travels to the front direction of the light emitting diode LED and the front luminance of the display device 700 can be improved so low-power driving can be possible.

Further, the second planarization layer 716 which surrounds the side surface of the light emitting diode LED includes a black material. Accordingly, , a black bank is not separately formed, which allows the thickness of the display device 700 to be reduced and the number of processes and the number of masks to be reduced to save the process cost and the time.

Further, a separate planarization layer is not formed above the second planarization layer 716 while the second connection electrode CE2 is still disposed. Accordingly, a separate process for forming an insulating layer is not use so, not only are the number of processes and the number of masks reduced, but also process cost and time can be saved.

Further, the adhesive layer AD includes a plurality of contact holes CH which surrounds the light emitting diodes LED, respectively. Accordingly, the adhesive layer AD disposed below the light emitting diode LED can be covered by the first connection electrode CE1 and the first reflective electrode RE1, except for a surface which is in contact with the light emitting diode LED. Therefore,any light emitted from the light emitting diode which travels in a direction in which the adhesive layer AD is disposed is reflected by the first connection electrode CE1 and the first reflective electrode RE1 to travel to the top of the light emitting diode LED. Accordingly, a problem where light emitted from the light emitting diode LED is guided in the adhesive layer AD and not emitted to the outside can be suppressed. Accordingly, in the display device 700 according to still another embodiment of the present disclosure, the overall luminance and the front luminance of the light emitting diode LED are improved so the low power driving of the light emitting diode LED can be possible.

Further, the first connection electrode CE1 and the first reflective electrode RE1 are electrically connected in each of the contact holes CH of the adhesive layer AD. Therefore, a contact area of the first connection electrode CE1 and the first reflective electrode RE1 can be increased and a line resistance between the first connection electrode CE1 and the first reflective electrode RE1 and between the first connection electrode CE1 and the driving transistor DT can be reduced.

The embodiments of the present disclosure can also be described as follows. According to an aspect of the present disclosure, a display device includes a substrate in which a plurality of sub pixels are defined; a plurality of driving transistors in each of the plurality of sub pixels; a plurality of light emitting diodes in each of the plurality of sub pixels; a first connection electrode covering a part of a lower side surface of the plurality of light emitting diodes and formed of a reflective conductive material; and a second connection electrode in contact with top surfaces of the light emitting diodes and formed of a transparent conductive material.

The display device can further include a first planarization layer on the driving transistors; and a second planarization layer between the first connection electrode and the second connection electrode and having a thickness thinner than a thickness of the light emitting diodes. The second planarization layer can include a black material.

The display device can further include a power line on the substrate; a plurality of first reflective electrodes connected to the driving transistors; a plurality of second reflective electrodes connected to the power line; and an adhesive layer on the plurality of first reflective electrodes and the plurality of second reflective electrodes. The first connection electrode can be in contact with a top surface of the adhesive layer. The display device can further include a third planarization layer between the second planarization layer and the second connection electrode.

The third planarization layer can cover a side surface of the second planarization layer and a side surface of the first connection electrode. The third planarization layer can include a plurality of contact holes which exposes a part of the top surfaces of the second reflective electrodes and the second connection electrode and the second reflective electrodes can be electrically connected in the contact holes of the third planarization layer.

A width of a bottom surface of the second planarization layer can be equal to a width of a top surface of the first connection electrode. The second planarization layer can cover a side surface of the first connection electrode. A top surface of the second planarization layer can be in contact with a bottom surface of the second connection electrode.

The adhesive layer can include a plurality of contact holes surrounding each of the light emitting diodes. The contact holes of the adhesive layer can expose a part of top surfaces of the first reflective electrodes and the first connection electrode can be in contact with top surfaces of the first reflective electrodes in the contact holes of the adhesive layer.

According to another aspect of the present disclosure, a display device includes a substrate in which a plurality of sub pixels are defined; a plurality of driving transistors in each of the sub pixels; a first planarization layer on the driving transistors; a plurality of light emitting diodes on the first planarization layer in each of the sub pixels; a first connection electrode electrically connected to the light emitting diodes and formed of a reflective conductive material; a second connection electrode electrically connected to the light emitting diodes and formed of a transparent conductive material; and a second planarization layer between the first connection electrode and the second connection electrode. The second planarization layer includes a black material.

Each of the light emitting diodes can include a first semiconductor layer; an emission layer on the first semiconductor layer; a second semiconductor layer on the emission layer; a first electrode on the first semiconductor layer; and a second electrode on the second semiconductor layer. The first connection electrode can be electrically connected to the first electrode and the second connection electrode can be electrically connected to the second electrode.

The second planarization layer can be disposed on the first connection electrode and the second planarization layer can overlap the first electrode, but may not overlap the emission layer. The display device can further include a third planarization layer covering a part of upper side surfaces of the light emitting diodes exposed by the second planarization layer. The third planarization layer can cover a top surface and a side surface of the second planarization layer.

A planar shape of the second planarization layer can be the same as a planar shape of the first connection electrode. The second planarization layer can include a plurality of contact holes and the second connection electrode can be disposed in the contact holes. The display device can further include a power line on the substrate; and an adhesive layer on the power line and the driving transistors. The adhesive layer can include a plurality of contact holes surrounding each of the light emitting diodes.

Although the embodiments of the present disclosure have been described in detail with reference to the accompanying drawings, the present disclosure is not limited thereto and can be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a driving transistor on the substrate;
an adhesive layer on the substrate;
a light emitting diode on the adhesive layer and overlapping with the driving transistor and having a first semiconductor layer on the adhesive layer, an emission layer on the first semicondutor layer, a second semiconductor layer on the emission layer, a first electrode on the first semiconductor layer, and a second electrode on the second semiconductor layer, wherien the first electrode is disposed closer to the substate than the emission layer, and the second electrode is disposed higher than the first electrode;
a reflective connection electrode covering a lower side surface of the light emitting diode and the first electrode and electrically connecting the first electrode to the driving transistor; and
a transparent connection electrode overlapping the reflective connection electrode, contacting a top surface of the light emitting diode and electrically connecting the second electrode to a power line on the substrate.

2. The display device according to claim 1, further comprising:
a first planarization layer covering the driving transistor; and
a second planarization layer includin a black material disposed between the reflective connection electrode and the transparent connection electrode and having a thickness thinner than a thickness of the light emitting diode.

3. The display device according to claim 2, further comprising:
a first reflective electrode connected to the driving transistor; and
a second reflective electrode connected to the power line and the transparent connection electrode,
wherein the adhesive layer covers the first reflective electrode and the second reflective electrode, and
wherein the reflective connection electrode contacts a top surface of the adhesive layer.

4. The display device according to claim 3, further comprising:
a third planarization layer between the second planarization layer and the second connection electrode,
wherein the third planarization layer covers a side surface of the second planarization layer and a side surface of the reflective connection electrode,
wherein the third planarization layer includes a contact hole exposing a part of the top surface of the second reflective electrode, and
wherein the transparent connection electrode contacts the second reflective electode in the contact hole of the third planarizatin layer.

5. The display device according to claim 3, wherein the reflective connection electrode and the first reflective electrode reflects light and the first reflective electrode reflect light to a front direction of the light emitting diode and through the transparent connection electrode.

6. The display device according to claim 2, wherein a width of a bottom surface of the second planarization layer is equal to a width of a top surface of the reflective connection electrode.

7. The display device according to claim 2, wherein the second planarization layer covers side surfaces of the reflective connection electrode.

8. The display device according to claim 7, wherein a top surface of the second planarization layer contacts a bottom surface of the transparent connection electrode.

9. The display device according claim 1, wherein the adhesive layer includes first and second contact holes surrounding the light emitting diode,
wherein the reflective connection electrode contacts a top surface of the first reflective electrode in the first contact hole of the adhesive layer, and
wherein the second reflective electode contacs the voltage line in the second contact hole of the adhesive layer.

10. The display device according to claim 1, wherein the first semiconductor layer has a thickness in an area overlapping the emission layer larger than a thickness in an area overlapping the first electrode such that the first electrode and the emission layer are disposed on different planes.

11. The display device according to claim 1, further comprising:
an encapsulation film encapsulating the light emitting diode and having first and second contact holes respectively exposing the first electrode and the second electrode such that the reflective connection electrode contacts the first electode, and the transparent connection electrode contacts the second electrode.

12. The display device according to claim 11, wherein the reflective connection electode directly contacts the adhesive layer and the encapsulation film of the light emitting diode.

13. The display device according to claim 2, wherein the second planarization layer is disposed on the reflective connection electrode, and
wherein the second planarization layer overlaps the first electrode, but does not overlap the emission layer.

14. The display device according to claim 13, further comprising:
a third planarization layer covering a part of upper side surfaces of the light emitting diode exposed by the second planarization layer,
wherein the third planarization layer covers a top surface and a side surface of the second planarization layer.

15. The display device according to claim 14, wherein a planar shape of the second planarization layer is the same as a planar shape of the reflective connection electrode.

16. The display device according to claim 13, wherein the second planarization layer includes a contact hole, and
wherein the second connection electrode is disposed in contact hole of the second planarization layer.

17. The display device according to claim 1, wherein the adhesive layer includes a reflective pigment.

18. The display device according to claim 17, wherein the adhesive layer includes a black pigment.
